(19) United States
(12) Patent Application Publication
(10) Pub. No.: US 2008/0236495 A1
(43) Pub. Date: Oct. 2, 2008

(54) Showerhead for chemical vapor deposition (CVD) apparatus

(75) Inventor: Gary S. Tompa, Belle Mead, NJ (US)

Correspondence Address: William L. Botjer, P. O. Box 478, Center Moriches, NY, 11934, US

(73) Assignee: Structured Materials Inc.

(21) Appl. No.: 12/079,557

(22) Filed: Mar. 27, 2008

Related U.S. Application Data
(60) Provisional application No. 60/920,125, filed on Mar. 27, 2007.

(51) Int. Cl. C23C 16/00

(52) U.S. Cl. 118/724; 118/715

(57) ABSTRACT

A reactant vapor distribution assembly for Chemical Vapor Deposition (CVD) apparatus which includes an upper flange which has a plenum disposed on its lower face and vapor injectors for injecting reactant vapors into the plenum. The distribution assembly also includes a lower flange having a peripheral rim surrounding a lower wall and a plenum on its upper face, certain of the vapor injectors are used to inject reactant vapors into this plenum. The lower flange includes fluid channels bored in the lower wall beneath the plenum and a number of gas flow openings bored in the lower wall of the lower flange to permit the precursor gases to flow from the plenum into the deposition chamber. The fluid channels may be used to heat or cool the flange. The lower flange has no welds or joints facing the hostile environment of the deposition chamber and all critical parts of the lower flange may be formed from a single billet of material.

### REFERENCE TO RELATED APPLICATIONS

This application claims priority from U.S. provisional application Ser. No. 60/920,125 filed Mar. 27, 2007.

### BACKGROUND AND SUMMARY OF THE INVENTION

This application is directed to a showerhead assembly within the preferred embodiment of Chemical Vapor Deposition (CVD) apparatus and more specifically to an improved showerhead design allowing cooling and uniform distribution of the reactant gases in a deposition reactor.

Chemical Vapor Deposition (CVD) systems are widely used to deposit elemental, alloy and compound films in the manufacture of electronic devices, such as integrated circuits formed by the sequential or simultaneous deposition of compounds upon a heated substrate, which is usually in the form of a wafer that is typically mounted on a “susceptor” which may or may not rotate. A showerhead provides distribution and passage for one or more reactant gases with the deposition chamber. The reactants are transported to the surface of the substrate, in the gas phase, by typically one or more carrier gases. The elements deposit on the wafer surface, forming the desired compound and any undesirable by-products are pumped away in a gaseous form. A heating element (filament) is mounted below the susceptor and heats the wafers.

In many CVD applications, wherein films are formed at a hot surface by the thermal driven reaction of precursor vapors, the mechanism that heats the surface to drive the surface thermal driven reactions may also radiate sufficient heat to generate gas phase reactions and or heat the vapor inlet mechanism sufficiently to drive thermal reactions at the vapor inlet mechanism. Reactions at the precursor inlet mechanism, commonly called a showerhead, are generally detrimental to the process because such coatings formed by the reactions can disturb or otherwise block desired flow patterns and or such coatings may flake off generating particles and the coatings may also act as a source of an element that may not be desired in a subsequent layer of a multilayer deposition.

The present invention is directed to a reactant vapor distribution assembly for Chemical Vapor Deposition (CVD) apparatus includes an upper flange which includes a plenum disposed on its lower face and vapor injectors for injecting reactant vapors into the plenum. The distribution assembly also includes a lower flange having a peripheral rim surrounding a lower wall and a plenum on its upper face, certain of the vapor injectors are used inject reactant vapors into this plenum. The lower flange includes fluid channels bored in the lower wall beneath the plenum and a number of gas flow openings drilled through the lower wall of the lower flange to permit the precursor gases to flow from the plenum. The fluid channels may be used to heat or cool the flange. The lower flange has no welds or joints facing the hostile environment of the deposition chamber and all critical parts of the lower flange may be formed from a single billet of material.

This work builds upon and improves upon our prior work, wherein we disclosed aspects of integrating showerhead cooling mechanisms. Many prior showerhead designs were constructed of a multiplicity of tubes, plates and flanges which had to carefully welded together into a gastight assembly. However every weld is a potential failure point. The present approach is directed to a showerhead design wherein no process side surface is exposed to welds (eliminating the potential of thermal cycling or other stress induced leaks), further it includes a showerhead design wherein the precursor gases may be introduced separately from one another (minimizing prereactions).

The showerhead also includes a mechanism wherein the precursor concentrations can be varied radially, thus improving uniformity of the deposit; as well as canceling depletion effects of consumed precursors forming in the deposit. The showerhead further provides a uniform carrier gas flow into the deposition chamber which promotes uniform laminar flow without recirculation. By the ordering and assemblage of components in the assembly the showerhead face closest to the heat source is temperature controlled by thermal regulating fluid flow. A large window for optical access to the deposition plane through the showerhead is also provided (thus allowing a multitude of deposition optical monitors and or imagers—such as temperature, deposition rate, bandgap, stress, and so on).

By adding a top flange fluid channel in this arrangement, we also have the option to heat or cool the entire assembly and thereby set a temperature that eliminates any condensation and mitigates the pre-reaction issue. An additional feature is that an electrode can be inserted in the upper or lower plenums such that at either level, but separate from the process reactor, can generate reactive ionic, excited or non molecular species for subsequent flow into the deposition reactor.

It should also be noted that this structure can also effectively be modified to allow some gases to heat on the way into the reactor; wherein a diffuser forms the lowest face of the showerhead so that a more contiguous gas flow is achieved across the whole surface. In this case the more thermally sensitive reactants are still distributed through the narrow holes 80 as shown in FIG. 3b, but other portions just through this final heated lower diffuser plate. Further, the lower diffuser plate can be made of ceramic to be less thermally conductive. Further, channels can be placed in the lower portion of the showerhead assembly that can in turn be filled with vaporizable material. In this way, additional elements or compounds, in the form of vapors, can be contributed to the growing material. It should also be noted that while the assemblies have been shown downwardly directed, but could equally be inverted for gas flow to be generally upward.

### PUBLISHED REFERENCES

| | | |
|---|---|---|
| EP 0 697 749 | Crawley | Dec. 20, 1995 |
| U.S. Pat. No. 5,595,606 | Fujikawa | Jan. 21, 1997 |
| U.S. Pat. No. 5,624,498 | Lee | Apr. 29, 1997 |
| U.S. Pat. No. 6,533,867 | Doppelhammer | Mar. 18, 2003 |
| US 2006/0021574 | Armour | Feb. 02, 2006 |
| US 2007/0248515 | Tompa | Oct. 27, 2007 |

### BRIEF DESCRIPTION OF THE DRAWINGS

FIG. 1 illustrates a general overview of a Chemical Vapor Deposition (CVD) System;

FIG. 2a is an exploded view, looking downwardly, of the showerhead assembly in accordance with the present invention;

FIG. 2b is an exploded view, looking upwardly, of the showerhead assembly in accordance with the present invention;

FIG. 3a is a perspective view, looking downwardly, of the lower showerhead flange in accordance with the present invention;

FIG. 3b is a perspective view, looking upwardly, of the lower showerhead flange in accordance with the present invention;

FIG. 3c is a sectional view cut along a horizontal plane of lower wall of the lower flange of the showerhead assembly;

FIG. 3d is a sectional view cut along a vertical plane of the lower flange of the showerhead assembly;

FIG. 4 is an exploded view, looking upwardly, of the showerhead assembly in accordance with a second embodiment of the present invention;

FIG. 5a is an exploded view, looking downwardly, of the lower flange of the showerhead assembly in accordance with a third embodiment of the present invention; and

FIG. 5b is a sectional view cut along a vertical plane of the lower flange of the showerhead assembly of FIG. 5a.

### DESCRIPTION OF THE PREFERRED EMBODIMENTS

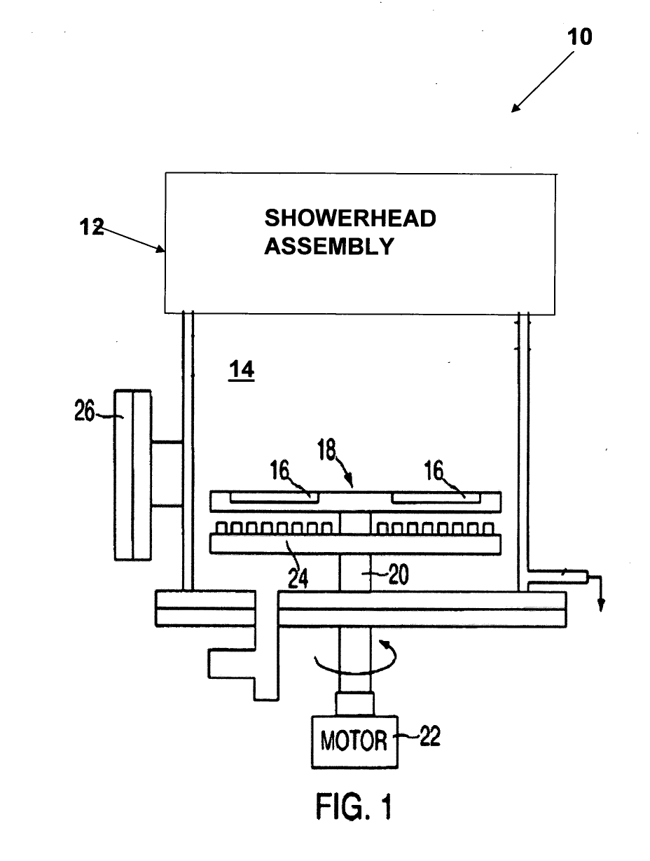

FIG. 1 illustrates schematically a Chemical Vapor Deposition (CVD) System 10 which, in general overview: includes a reactor chamber 14, sealed to the atmosphere, to which is mounted a vapor distribution housing in the form of a showerhead assembly 12 for the film growth reactant gases which is the portion of the Chemical Vapor Deposition (CVD) System 10 to which the present invention is directed. Showerhead assembly 12 (described in detail in the drawing figures and text below) directs the reactant gases over one or more substrate wafers 16, mounted, in this example, on a rotatable susceptor 18 which is rotated through a shaft 20 by a motor 22 mounted externally from reactor chamber 14, and which are heated by a heater unit 24. The reactant and carrier gases generated by external sources (not shown) are distributed though the distribution housing and flow over heated wafers 16 where the gases will decompose (react at the wafer surface) and deposit their compounds, thereafter an exhaust unit 26 will remove the spent gases from reactor chamber 14.

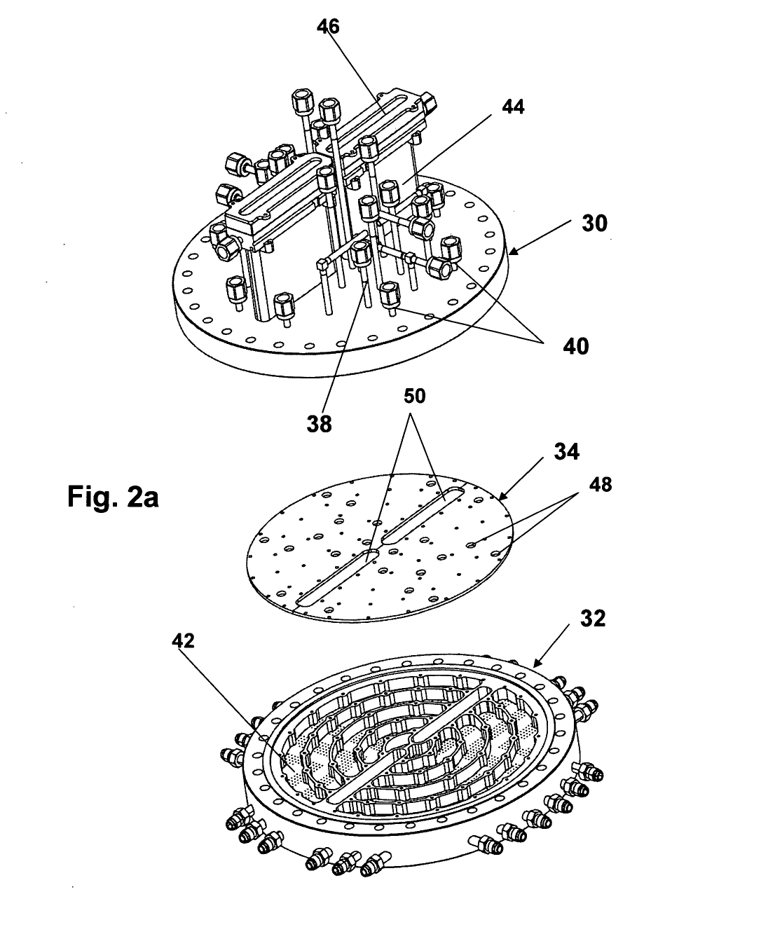

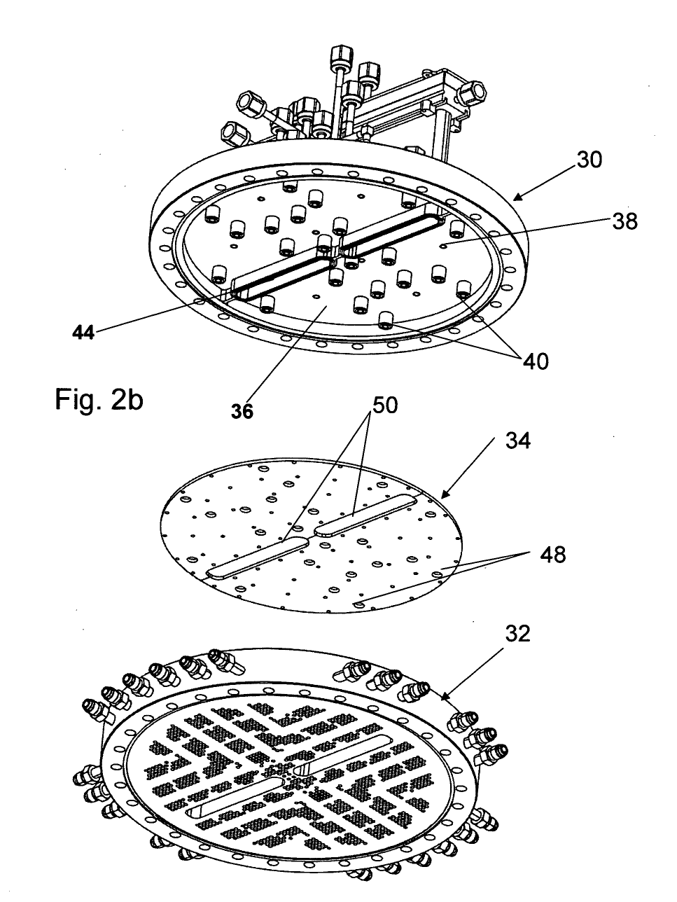

FIG. 2a is an exploded view of showerhead assembly 12 looking downwardly, which includes an upper showerhead flange 30, a lower showerhead flange 32 and a uniform gas flow diffuser 34 located therebetween. As best seen in FIG. 2b located on the underside of upper showerhead flange 30 is an upper plenum 36. A series of uniform push/carrier gas injectors 38 (within which some precursors can also be supplied) are mounted to upper showerhead flange 30 and extend to upper plenum 36 to deliver gases thereto. Other precursor injectors 40 are mounted to upper showerhead flange 30 extend through upper plenum 36 and gas flow diffuser 34 to deliver gases to lower plenum zones 42 located in lower showerhead flange 32. Also mounted to upper showerhead flange 30 are viewports 44 which extend through upper showerhead flange 30 and are closed by gastight windows 46 to permit the operators of CVD system 10 to observe the deposition process. Gas is typically flowed over windows 46 to mitigate coating build-up on the window. The window flanges may also be water cooled to minimize effects of window material heat absorption

Uniform gas flow diffuser 34 is located between and separates upper plenum 36 of upper showerhead flange 30 and lower plenum zones 40 of lower showerhead flange 32. Gas flow diffuser 34 is constructed of a gas permeable material, such as porous stainless steel, molybdenum, other metals, or ceramics to permit gases from upper plenum 36 of upper showerhead flange 30 to diffuse into lower plenum zones 40 of lower showerhead flange 32. The porosity of gas flow diffuser 34 is generally sized with the flow to assure that the pressure in the upper plenum is greater than that in the lower plenum. Gas flow diffuser 34 thus mitigates back flow from the lower plenum 42 to upper plenum 36. Uniform gas flow diffuser 34 also includes openings 48 which are aligned with precursor injectors 40 to permit direct injection of precursor gases into lower plenum zones 40. Elongated openings 50 in uniform gas flow diffuser 34 align with view ports 44 in upper showerhead flange 30 to permit unobstructed viewing of the deposition process.

The design of the lowermost portion of a showerhead assembly is of critical importance to the integrity of the CVD system since it is exposed to the environment of deposition chamber 13. In the present invention all critical components of lower showerhead flange 32 can be preferably machined from a single billet of material, such as stainless steel, without any welds being exposed to the process atmosphere, eliminating the potential of thermal cycling or other stress induced leaks.

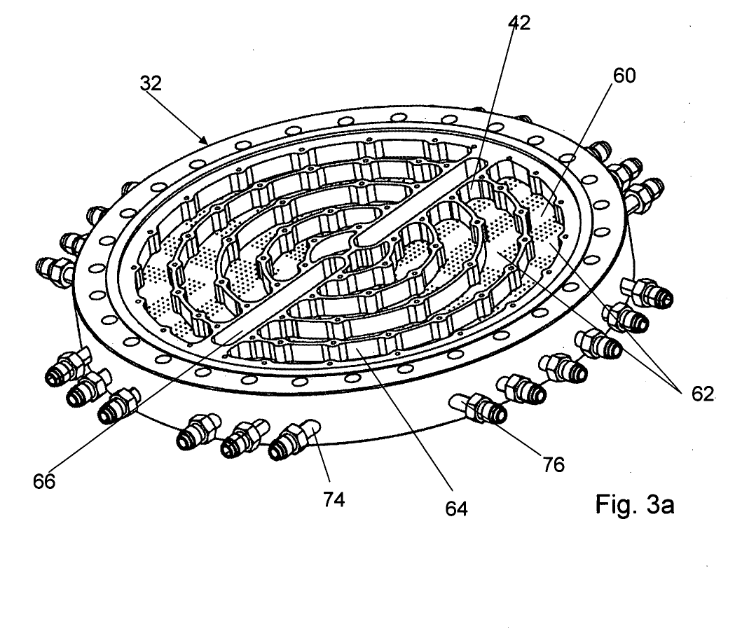

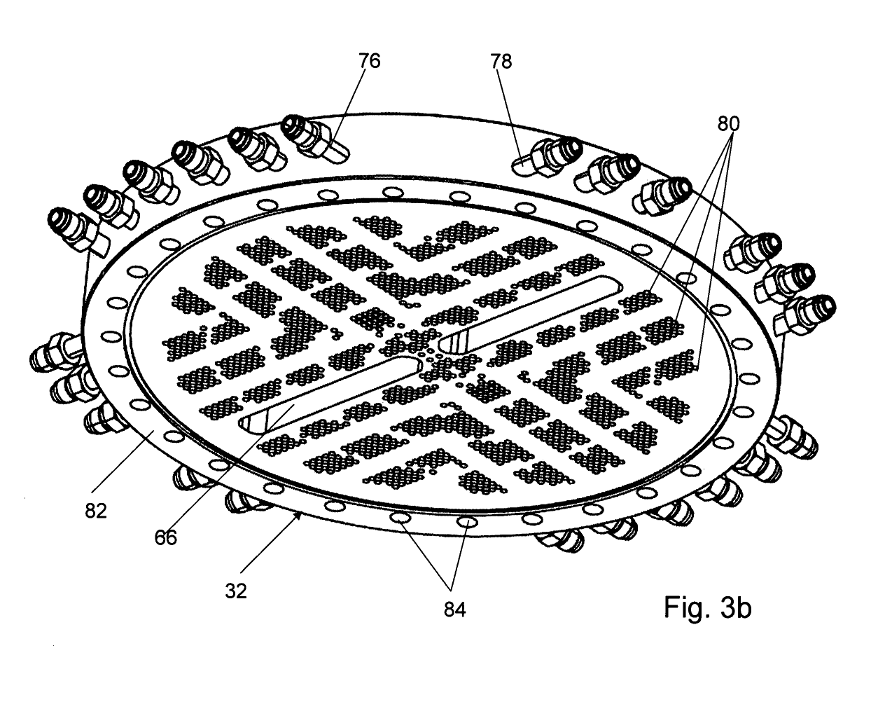

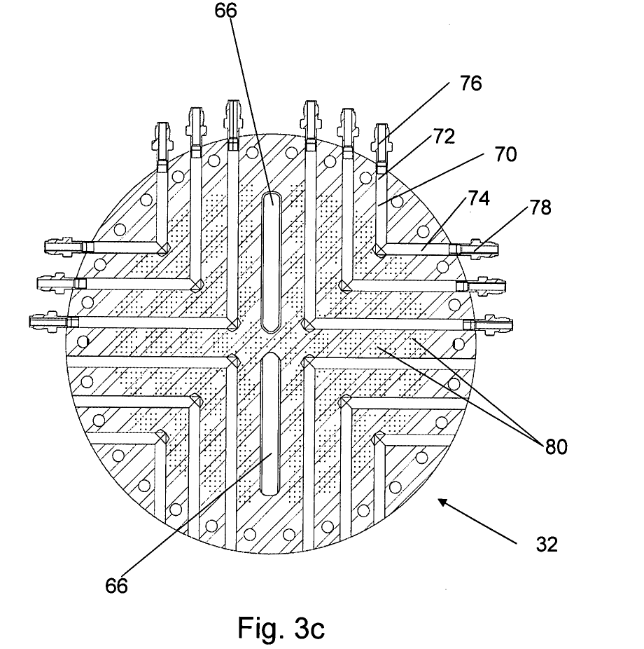

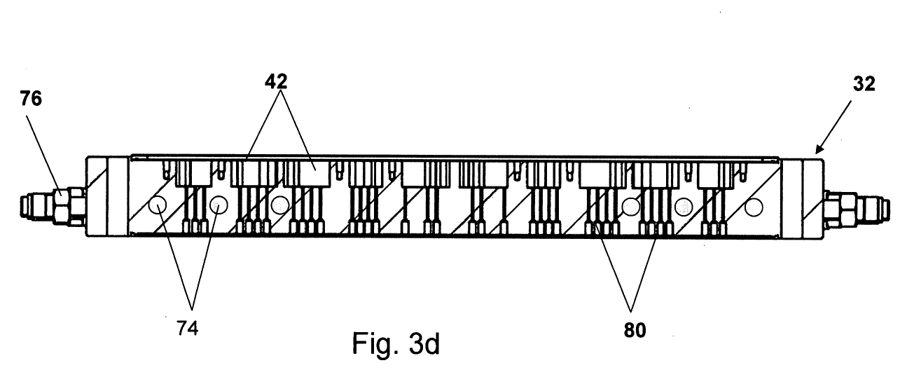

FIG. 3a and 3b are perspective views, looking downwardly and upwardly respectively, of lower showerhead flange 32 which includes a relatively thick lower wall 60 and precursor injections zones 62 formed by concentrically configured walls 64 within plenum 42 for precursor injection. FIG. 3c is a sectional view cut along a horizontal plane of lower wall 60 and FIG. 3d is a sectional view cut along a vertical plane of lower showerhead flange 32. Walls 64 within plenum 42 form individual plenums (i.e. injections zones 62) for precursor injection from precursor injectors 40 in upper showerhead flange 30. Injection zones 62 formed by walls 64 permit the precursor gases to be introduced separately from one another thus minimizing pre-reactions. Furthermore, radially extending walls may also be added to plenum 42 to further isolate the precursor vapors from one another. Elongated openings 66 extend through plenum 42 and lower wall 60 of lower showerhead flange 32 to align with view ports 44 in upper showerhead flange 30 to permit viewing of the deposition process.

As noted above lower wall 60 of lower showerhead flange 32 is relatively thick to permit a series of fluid channels 70 to be “gun drilled” therethrough, as illustrated in FIGS. 3c and 3d which are cross sections of lower wall 60 of lower showerhead flange 32. Each fluid channel 70 may be formed from a first bore 72 in lower wall 60 which intersects a second bore 74 in lower wall 60 at a right angle or other suitable angle. A fluid inlet fitting 76 is joined, such as by way of example welding, to bore 72 and a fluid outlet fitting 78 is joined to bore 74. Fittings 76 and 78 are connected to an external source of fluid such as water, or other suitable coolant (or heated) liquid. Coolant liquid flowing within channels 70 cools lower showerhead flange 32 and assures that the precursors do not decompose in flange 32. As noted above rather than a coolant, certain processes may require that the fluid flowing through channels 70 be used to heat the showerhead assembly, the present design readily accommodates this modification.

A multiplicity of gas flow openings 80 are drilled vertically through lower wall 60 of lower showerhead flange 32 to permit the precursor gases to flow form plenum 42 to the interior of CVD system 10 and thereafter to substrate wafers 16. It is to be noted that gas flow openings 80 are positioned so that they do not intercept water channels 70 so as to maintain the water tightness of channels 70. This can be best seen in FIG. 3b wherein the outlines of channels 70 are seen in lower wall 60 of lower showerhead flange 32 without any gas flow openings 80 drilled therein.

Lower showerhead flange 32 includes a circular rim 82 which includes a series of bores 84 through which rim 82 will be bolted to the upper rim of the deposition chamber of CVD reactor 10 by bolts which also serve to secure upper showerhead flange 30 to lower showerhead flange 32. As such, fluid inlet fittings 76 and fluid outlet fittings 78 are located outside of deposition chamber 13 of CVD reactor 10. Thus only the bottom surface of lower wall 60 of lower showerhead flange 32 faces the heated substrates and the flowing coolant assures that the precursors do not decompose in showerhead assembly 12. The design described herein can maintain the face of the showerhead at less than 100° C. when facing a heat source ranging from room temperature to greater than 1650° C. All of the critical components of lower showerhead flange 32 are preferably machined from the same billet of material as a unitary component by standard CNC equipment which assures a gastight assembly as every weld is a potential failure point.

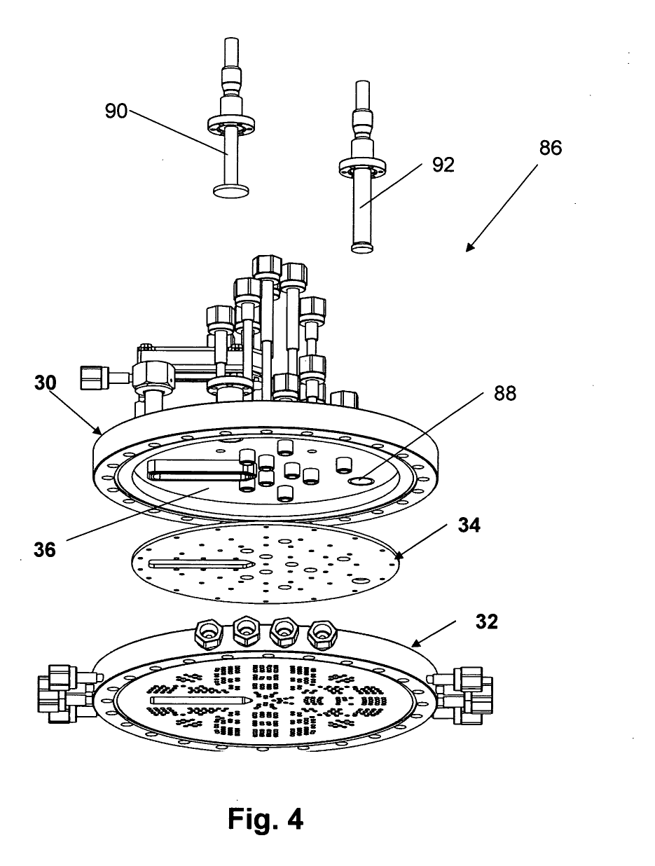

FIG. 4 is an exploded view, looking downwardly, of a showerhead assembly 86 in accordance with a second embodiment of the present invention. In this embodiment one of the viewports in upper showerhead flange 30 has been replaced with an opening 88 to permit the insertion of one or more plasma generating electrodes to generate ionic, excited and or elemental gas phase species of the reactant vapors. As shown in the drawing a first electrode 90 has a shorter shaft which may be used to generate a plasma in plenum 36 in upper showerhead flange 30. A second electrode 92 has a relatively longer shaft which may be used to generate a plasma in plenum 42 in lower showerhead flange 32. Upper showerhead flange 30 may preferably include fluid channels so as to dissipate the heat caused by the generated plasma. It should be noted that upper showerhead flange 30 could include two openings 88 to permit both electrodes 90 and 92 to be used simultaneously and that an electrode can be used in conjunction with two viewports in upper showerhead flange 30.

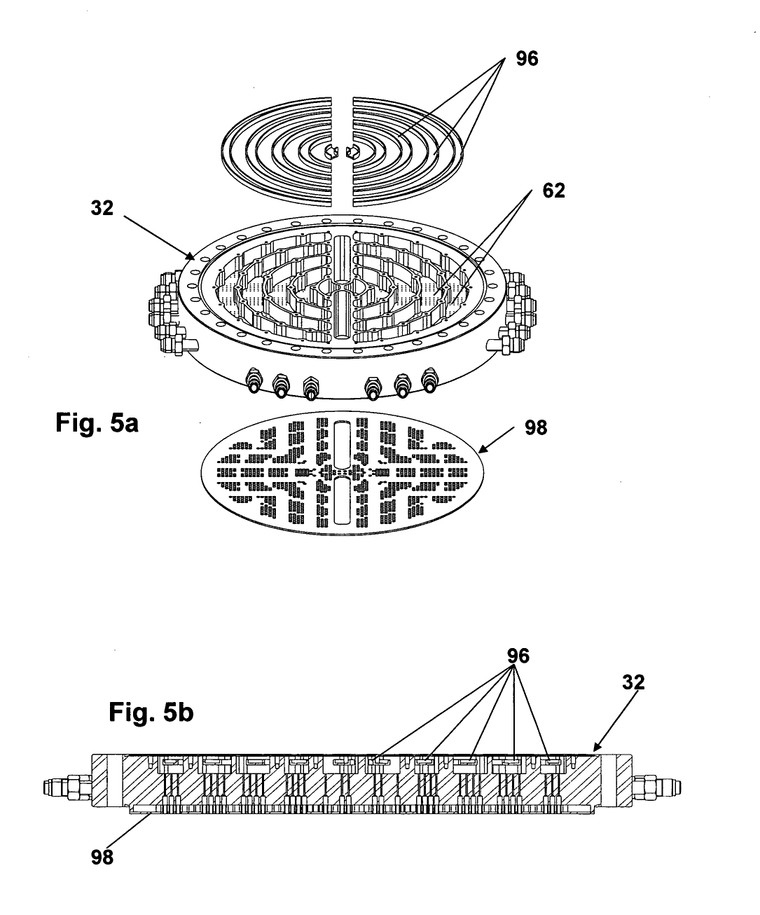

FIG. 5a is an exploded view, looking downwardly, of lower flange 32 of the showerhead assembly in accordance with a third embodiment of the present invention; and FIG. 5b is a sectional view cut along a vertical plane of lower flange 32. This embodiment includes a series of semicircular, U-shaped in cross-section, troughs 96 which are configured to be positioned within injections zones 62 formed in plenum 42 in lower flange 32. Troughs 96 are used to hold a material within the showerhead and within the gas flow and at a temperature that creates vapors at a specific vapor pressure and when flow is passed over it is used to carry the vapors into the reactor. A port, not shown, in the showerhead can be used to refill the materials. Most advantageous is a material which melts so it can more easily fill troughs 96 uniformly.

Also included in this embodiment is a cover plate 98 disposed on the underside of lower flange 32. Cover plate 98 is used to form a third and lowest level plenum. Cover plate 98 is porous so that it can also pass a flow of gas into the reactor uniformly. Further, the gas flowing through cover plate 98 can be heated as it passes through porous cover plate 98 with heat from radiation from the heated wafers. Preheating some gases over others can help enhance the reaction rate at the surface, but not so much as to create to high a rate of gas phase pre-reactions. Further, the other gases coming through gas flow openings 80 lower flange 32 remain essentially cool. The two gas flows combine to make a uniform flow down to the heated surface.

The invention has been described with respect to preferred embodiments of apparatus for film deposition on a wafer surface. However, as those skilled in the art will recognize, modifications and variations in the specific details which have been described and illustrated may be resorted to without departing from the spirit and scope of the invention as defined in the appended claims

What is claimed is:

1. A reactant vapor distribution assembly for a Chemical Vapor Deposition (CVD) apparatus comprising:
a) an upper flange assembly, said upper flange assembly including
i) a plenum disposed on its lower face;
ii) a plurality of vapor injectors, at least some of said vapor injectors being configured to inject reactant vapors into said plenum;
b) a lower flange assembly, said lower flange assembly having
i) a peripheral rim surrounding a lower wall,
i) a plenum disposed on its upper face defined by the peripheral rim and the lower wall, at least some of said vapor injectors being configured to inject reactant vapors into said plenum;
iii) a series of fluid channels bored in said lower wall beneath said plenum; and
iv) a multiplicity of gas flow openings drilled through the lower wall of lower flange to permit the precursor gases to flow from the plenum.

2. The distribution assembly as claimed in claim 1 further including at least one wall upstanding from said lower wall of said lower flange assembly, said upstanding walls serving to divide said plenum of said lower flange assembly into individual plenums.

3. The distribution assembly as claimed in claim 1 further including a gas flow diffuser located between the plenum of upper showerhead flange and the plenum of lower showerhead flange, the gas flow diffuser being constructed of a gas permeable material to permit gases from the plenum of the upper showerhead flange to diffuse into the plenum of the lower showerhead flange.

4. The distribution assembly as claimed in claim 3 further including at least one viewport opening disposed in said upper flange assembly said lower flange assembly and said gas flow diffuser to permit viewing of the deposition process.

5. The distribution assembly as claimed in claim 2 wherein said peripheral rim, said lower wall and said at least one upstanding wall are integrally formed from a single piece of material.

6. The distribution assembly as claimed in claim 3 further including an opening in said upper flange assembly to permit insertion of a plasma generating means so as to enable the generation of a plasma in at least one of the plenum in the upper flange assembly and the plenum in the lower flange assembly.

7. The distribution assembly as claimed in claim 1 wherein said lower flange assembly includes means to secure it to the deposition chamber of the CVD system, the lower face of the lower wall of the lower flange assembly being disposed within said deposition chamber but without presenting any joins or welds to the environment of the deposition chamber.

8. The distribution assembly as claimed in claim 1 wherein the peripheral rim of said lower flange assembly includes coolant inlet and outlet fittings to supply coolant to the fluid channels, said inlet and outlet fittings being located outside said deposition chamber when said lower flange assembly is secured to the deposition chamber of the CVD system.

9. The distribution assembly as claimed in claim 1 further including a material reservoir internal to the distribution assembly that is temperature controlled and useable as a replenishable vapor source.

10. The distribution assembly as claimed in claim 1 further including a porous cover plate disposed on the underside of the lower flange assembly forming a lowest level plenum, wherein the gas flowing through the cover plate can be heated with heat from radiation from the heated wafers as it passes therethrough.

11. A flange assembly for use in a reactant vapor distribution assembly for a Chemical Vapor Deposition (CVD) apparatus, said flange assembly comprising
a) a peripheral rim surrounding a lower wall,
b) a plenum disposed on its upper face defined by the peripheral rim and the lower wall, said plenum being configured to receive said reactant vapors;
c) a series of fluid channels bored in said lower wall beneath said plenum;
d) a multiplicity of gas flow openings drilled through the lower wall of lower flange to permit the precursor gases to flow from the plenum;
e) at least one wall upstanding from said lower wall of said flange assembly, said at least one upstanding wall serving to divide said plenum into individual plenums; and
f) said peripheral rim, said lower wall and said upstanding walls being integrally formed from a single piece of material.

12. The flange assembly as claimed in claim 11 wherein said assembly is machined from a single billet of stainless steel.

13. The flange assembly as claimed in claim 11 wherein said flange assembly includes means to secure it to the deposition chamber of the CVD system the bottom face of the lower wall of the flange assembly being disposed within said deposition chamber but without presenting any joins or welds to the environment of the deposition chamber.

14. The flange assembly as claimed in claim 11 wherein the peripheral rim of said flange assembly includes coolant inlet and outlet fittings to supply coolant to the fluid channels, said inlet and outlet fittings being located outside said deposition chamber of said flange assembly when said flange assembly is secured to the deposition chamber of the CVD system.

15. The flange assembly as claimed in claim 11 further including at least one viewport opening disposed in said flange assembly to permit viewing of the deposition process.

16. The flange assembly as claimed in claim 11 further including means for receiving at least one plasma generating means so as to enable the generation of a plasma in the plenum of the flange assembly.

17. The flange assembly as claimed in claim 11 further including a material reservoir internal to the flange assembly that is temperature controlled and useable as a replenishable vapor source.

18. The flange assembly as claimed in claim 11 further including a porous cover plate disposed on the underside of the flange assembly forming a lowest level plenum, wherein the gas flowing through the porous cover plate can be heated with heat from radiation as it passes therethrough.

18. The flange assembly as claimed in claim 11 wherein the fluid channels are supplied with a coolant to cool the assembly.

18. The flange assembly as claimed in claim 11 wherein the fluid channels are supplied with a heated fluid to heat the assembly.
